(19) United States
(12) Patent Application Publication
(10) Pub. No.: US 2012/0223361 A1
(43) Pub. Date: Sep. 6, 2012

(54) LOW-POWER CONSUMPTION TUNNELING FIELD-EFFECT TRANSISTOR WITH FINGER-SHAPED GATE STRUCTURE

(76) Inventors: Ru Huang, Beijing (CN); Zhan Zhan, Beijing (CN); Qianqian Huang, Beijing (CN); Yangyuan Wang, Beijing (CN)

(21) Appl. No.: 13/378,920

(22) PCT Filed: May 19, 2011
(86) PCT No.: PCT/CN11/74314

§ 371 Date: Dec. 16, 2011

(30) Foreign Application Priority Data
Mar. 1, 2011 (CN) 201110048595.4

(51) Int. Cl. H01L 29/78

(52) U.S. Cl. 257/105; 257/E29.255

(57) ABSTRACT

The present invention discloses a low-power consumption tunnelling field-effect transistor (TFET). The TFET according to the invention includes a source, a drain and a control gate, wherein the control gate extends towards the source to form a finger-type control gate, which includes an extended gate region and an original control gate region, and an active region covered by the extended gate region is also an channel region and is made of the substrate material. The invention employs a finger-shaped gate structure, and the source region of the TFET surrounds the channel so that the on-state current of the device is improved. In comparison with the conventional planar TFET, a higher on-state current and a steeper subthreshold slope may be obtained under the same process conditions and with the same active region size.

### Field of the Invention

The present invention relates to the field of logic devices and circuits in CMOS ultra large scale integration (ULSI), and in particular, to a tunneling field-effect transistor (TFET).

### BACKGROUND OF THE INVENTION

With the continual shrinkage of the device size, the negative effects such as short channel effect become more and more serious. The DIBL (Drain-Induced Barrier Lowering) effect and the Band-to-Band Tunneling effect make the off-state leakage current of the device become larger and larger. Moreover, as limited by the theory of KT/q, the subthreshold slope of a traditional MOSFET device cannot be reduced with the shrinkage of the device size. Therefore, with the reduction of the threshold voltage of the device, the subthreshold leakage current increases continually. Nowadays, the problem of static-state power consumption caused thereby has become a focal point for small-size device. In order to break through the theoretic limit of a subthreshold slope of 60 mv/dec for a conventional MOSFET, to lower the static-state power consumption of a device and also to lower the dynamic-state power consumption during the switching process simultaneously, a device with a novel switching-on mechanism needs to be employed. For a tunneling field-effect transistor (TFET) has a wide application prospect, because a switching-on mechanism of quantum-mechanical tunneling is employed so that the theoretic limitation on subthreshold region of a conventional MOSFET is broken through.

In the traditional planar silicon technology, the structure of a TFET is similar to that of a traditional MOSFET, and the control gate has a certain breadth length ratio, as shown in FIG. 1. At present, the main challenge faced by TFET is the insufficient driving current due to the limitation of the tunneling. Currently, there mainly exist the following methods for increasing the on-state current of a TFET: (1) reducing the thickness of the gate dielectric layer and increasing the dielectric constant of the gate dielectric layer so that the gate control capability is improved, wherein a high-K dielectric is employed and thus the process is relatively complex as compared with the method of growing a silicon dioxide gate dielectric; moreover, due to the influence of the gate leakage current, the thickness of the dielectric layer also has a limit value; 2) employing a semiconductor material with a narrow bandgap to reduce the width of tunneling barrier and increase the tunneling current; in this method, because other semiconductor materials are introduced, the cost and the process complexity are increased undoubtedly.

### SUMMARY OF THE INVENTION

It is an object of the present invention to provide a low-power consumption tunneling field-effect transistor with a finger-shaped gate structure. With the structure, it is able to increase the on-state current of device evidently by using the same active region area without changing the fabrication process.

The technical solutions of the present invention are as follows.

A low-power consumption tunneling field-effect transistor, including a source, a drain and a control gate, characterized in that, the control gate extends towards the source to form a finger-type control gate which specifically includes two parts: a finger-shaped gate which is formed by an extended gate region, and a main gate which is an original control gate region; the active region covered by the extended gate region is also a channel region and is made of a substrate material.

The number of finger-shaped gates is arbitrary, but the total width of finger-shaped gates is less than an implantation width of the source region so as to ensure that the finger-shaped gates are surrounded by the source region.

The width of the extended gate is arbitrary, so long as it is ensured that the total width of the finger-shaped gates is less than the implantation width of the source region so as to ensure that the finger-shaped gates are surrounded by the source region.

The gate width of the finger-shaped gate may also be properly reduced so that the channel region under the extended gate region may be depleted by the source junction built-in potential on both sides of the gate, thus the static-state leakage current of the device may be reduced. Depending on the doping concentrations of the channel and the source regions, the gate width of the finger-shaped gate is approximately less than 1-2 μm.

The length direction of the finger-shaped gate may be arbitrary, which is depending on the increase amount of current needed, but usually does not exceed the edge of the active region at the source.

A certain margin may be remained between the main gate and the drain region to suppress the bipolar on-state characteristic of the TFET; a certain margin may also be remained between the main gate and the source region, thus the main gate region may lose the control so that a better subthreshold slope is obtained.

The technical effects of the present invention are as follows.

1) Finger-shaped gate is employed to control the channel surface potential, so that the conduction band of the channel surface is lowered or the valence band of the channel surface is increased, and the electric field strength of the source junction is enhanced, which prompts the occurrence of band-to-band tunneling, thus an on-state current is generated.

2) A finger-shaped gate structure is employed, so that the channel is surrounded by the source region of the TFET, a large tunnelling area is realized, the on-state current of the device is increased, and at the same time the subthreshold slope is improved.

3) Increasing the length of the finger-shaped gate can most effectively improve the on-state current of the device.

In comparison with the conventional planar TFET, a higher on-state current and a steeper subthreshold slope may be obtained under the same fabrication process conditions and with the same active region size. In comparison with TFET of T-shaped gate, the TFET of finger-shaped gate utilizes the device area more effectively and further increases the current density.

### BRIEF DESCRIPTION OF THE DRAWINGS

FIG. 1 is a structural schematic diagram of a typical planar TFET; wherein, FIG. 1a is a schematic diagram of a typical planar TFET; and FIG. 1b is a plan view of a typical planar TFET;

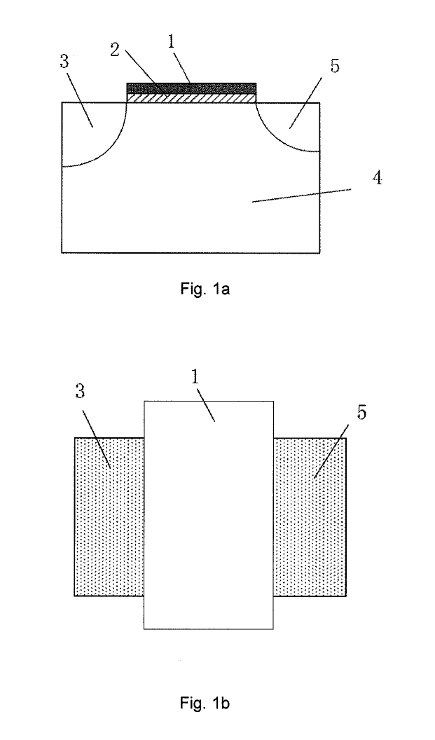

FIG. 2 is a planar structural schematic diagram of a TFET with finger-shaped gate according to the invention; wherein, FIG. 2a is a schematic diagram of the TFET with finger-shaped gate according to the invention; and

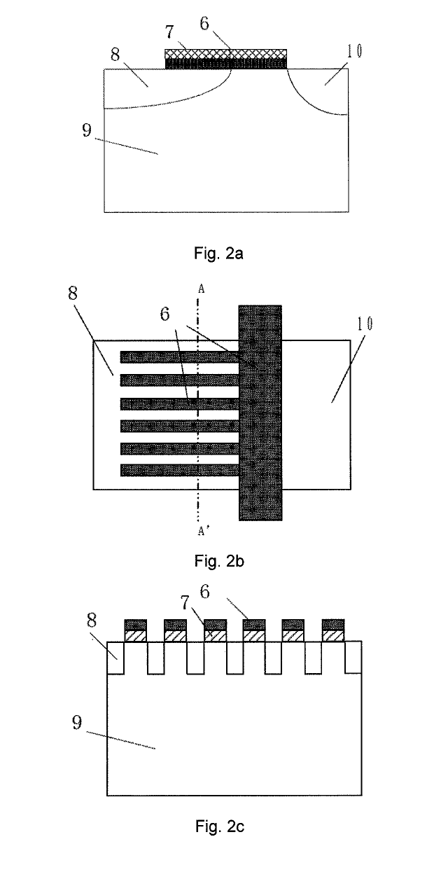

FIG. 2b is a plan view of the TFET with the finger-shaped gate according to the invention; and FIG. 2c is a sectional view along the direction AA′ (FIG. 2b) of the finger-shaped gate of the invention;

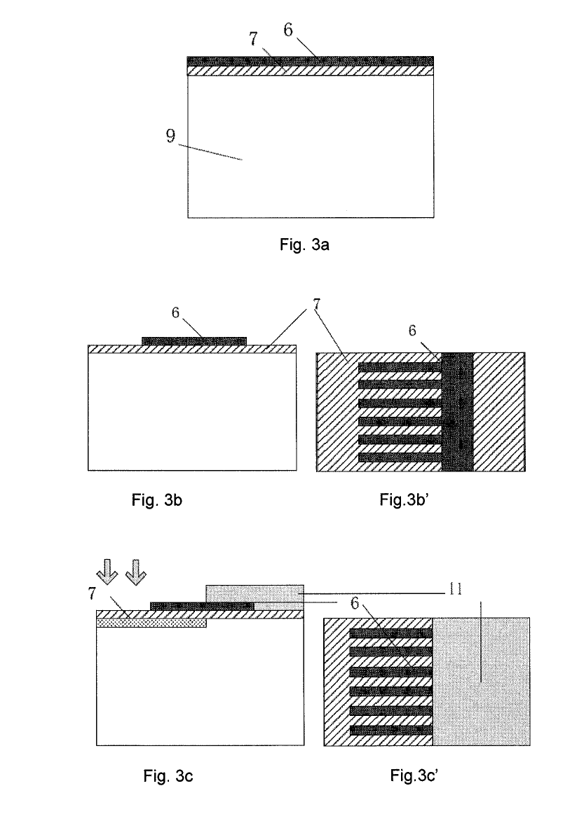

FIG. 3 shows the main processing steps for manufacturing the TFET with finger-shaped gate according to the invention, wherein, FIG. 3a shows a substrate after growing an oxide layer and depositing a polysilicon; FIG. 3b shows the substrate after lithographying an active region, and FIG. 3b′ is a plan view of FIG. 3b; FIG. 3c shows the procedure of the active region implantation process for source region, and FIG. 3c′ is a plan view of FIG. 3c; FIG. 3d shows the procedure of the active region implantation process in the drain region, and FIG. 3d′ is a plan view of FIG. 3d; FIG. 3e is a structural diagram of a low-power consumption tunneling field-effect transistor with a finger-shaped gate structure after a source-drain junction being formed, and FIG. 3e′ is a plan view of FIG. 3e; in FIG. 3a-3e:

1-control gate of the conventional TFET; 2-gate oxide layer of the conventional TFET; 3-source of the conventional TFET; 4-substrate of the conventional TFET; 5-drain of the conventional TFET; 6-control gate of the TFET according to the invention; 7-gate dielectric layer of the TFET according to the invention; 8-source of the TFET according to the invention; 10-drain of the TFET according to the invention; 9-substrate of the TFET according to the invention;

FIG. 4 is a comparison graph of the experimental results of the transfer characteristic curves of the conventional TFET, the TFET with T-shaped gate and the TFET with finger-shaped gate.

### DETAILED DESCRIPTION OF THE EMBODIMENTS

The invention will now be further illustrated via an example. It should be noted that the embodiment is disclosed for a better understanding of the invention. However, one skilled in the art may understand that various substitutions and modifications are possible without departing from the spirit and scope of the invention and the appended claims. Therefore, the invention should not be limited to the content disclosed in the embodiment, and the protection scope of the invention is defined by the claims of the invention.

The invention may be manufactured completely by employing the conventional TFET process flow, and the key point lies in the layout structure of the gate.

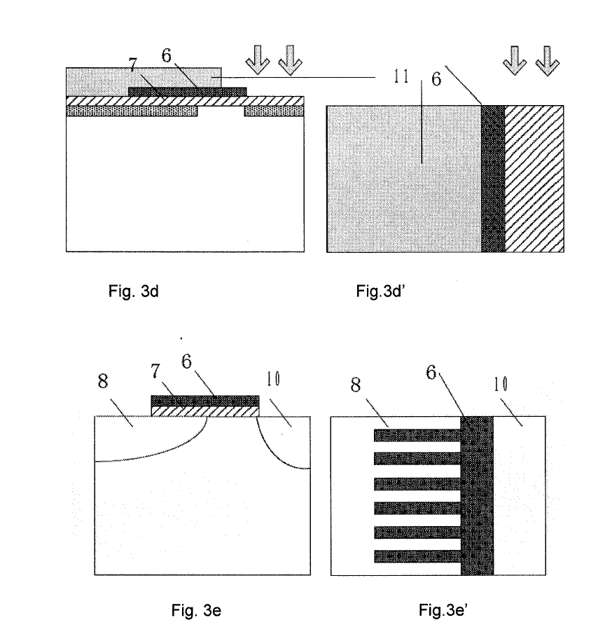

The specific implementation steps are as shown in FIG. 3.

1) A gate oxide layer 7 is grown on a substrate 9, wherein the smaller the gate thickness is, the better the gate control capability of the device will be, and the ideal value is approximately between 4 nm-20 nm. Then a polysilicon 6 is deposited, as shown in FIG. 3a.

2) A gate pattern 6 is formed by lithography, wherein the width of the finger-shaped gate is approximately 1 μm, the distance between the finger-shaped gates and the margin for the finger-shaped gate and the upper side, lower side and the left side of the source region are also approximately 1 μm, and then the source and drain implantation is to be performed by using the polysilicon layer as the hard mask, as shown in FIG. 3b. A photoresist 11 is coated on the drain region, and a source active region implantation is performed by using the photoresist 11 and the polysilicon 6 as the mask, and then the photoresist is removed, as shown in FIG. 3c.

3) A photoresist 11 is coated on the source region, and a drain active region implantation is performed by using the photoresist and the polysilicon 6 as the mask, and then the photoresist is removed, as shown in FIG. 3d.

4) A high-temperature thermal annealing is performed to activate the impurities in the source and drain so as to form a source region 8 and a drain region 10, as shown in FIG. 3e.

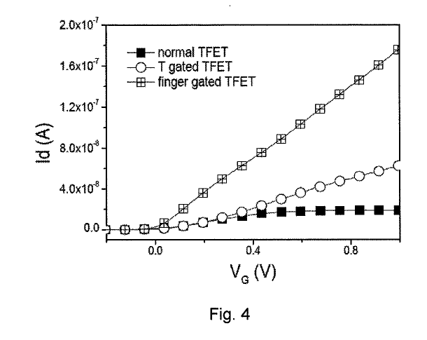

FIG. 4 is a comparison graph of the experimental results of the transfer characteristic curves of the conventional TFET, the TFET of T-shaped gate and the TFET of finger-shaped gate, wherein the TFET of finger-shaped gate has 3 fingers and the three types of devices have the same active region size. It can be seen that the TFET of finger-shaped gate may effectively increase the on-state current of the device and improve the driving performance of the device.

Although the invention has been disclosed hereinbefore by a preferred embodiment, it does not intend to limit the scope of the invention. Various variations and modifications can be made on the technical solutions of the invention or the technical solutions of the invention may be modified to a equivalent embodiment with equivalent variations by those skilled in the art using the above disclosed method and technical contents, without departing from the scope of the technical solution of the invention. Therefore, any simple change, equivalent variations and modifications made to the above embodiment according to the technical solution of the invention, without departing from the technical solutions of the invention, all pertain to the protection scope of the invention.

1. A low-power consumption tunneling field-effect transistor, including a source, a drain and a control gate, characterized in that, the control gate extends towards the source to form a finger-type control gate which comprises an extended finger-shaped gate region and an original control gate region, and an active region covered by the extended finger-shaped gate region is also a channel region and is made of a substrate material.

2. The low-power consumption tunneling field-effect transistor according to claim 1, characterized in that, the total width of the finger-shaped gate region is less than an implantation width of the active region in the source region.

3. The low-power consumption tunneling field-effect transistor according to claim 2, characterized in that, a gate width in the finger-shaped gate region is 5 nm-2 μm.

4. The low-power consumption tunneling field-effect transistor according to claim 1, characterized in that, a gap exists between the original control gate region and the drain region, in the range of 5 nm-2 μm.

5. The low-power consumption tunneling field-effect transistor according to claim 1, characterized in that, a gate dielectric is silicon dioxide or a high-K gate dielectric material.
